(19) United States
(12) Patent Application Publication
(10) Pub. No.: US 2013/0163073 A1
(43) Pub. Date: Jun. 27, 2013

(54) SOLID-STATE LASER AMPLIFIER, LASER LIGHT AMPLIFIER, SOLID-STATE LASER DEVICE, AND LASER DEVICE

(71) Applicant: Gigaphoton Inc., Tochigi (JP)

(72) Inventor: Shinji ITO, Tochigi (JP)

(73) Assignee: Gigaphoton Inc., Tochigi (JP)

(21) Appl. No.: 13/684,865

(22) Filed: Nov. 26, 2012

(30) Foreign Application Priority Data
Dec. 26, 2011 (JP) 2011-284327

(51) Int. Cl. H01S 5/00

(52) U.S. Cl. CPC H01S 5/0071
USPC 359/344

(57) ABSTRACT

A solid-state laser amplifier may include a first amplifying module including a first optical system having two focusing optical systems disposed so that the focal points of the two focusing optical systems essentially match at a first position, and a first solid-state laser element, disposed so that a surface into which laser light enters is tilted at essentially a Brewster's angle relative to an optical path of the laser light and a second amplifying module including a second optical system having two focusing optical systems disposed so that the focal points of the two focusing optical systems essentially match at a second position, and a second solid-state laser element, disposed so that a surface into which laser light that has passed through the first amplifying module enters is tilted at essentially a Brewster's angle relative to an optical path of the laser light.

### CROSS-REFERENCE TO RELATED APPLICATION

The present application claims priority from Japanese Patent Application No. 2011-284327 filed Dec. 26, 2011, the entire contents of which are hereby incorporated by reference.

### BACKGROUND

1. Technical Field

The present disclosure relates to solid-state laser amplifiers, laser light amplifiers, solid-state laser devices, and laser devices.

2. Related Art

The miniaturization and increased levels of integration of semiconductor integrated circuits has led to a demand for increases in the resolutions of semiconductor exposure devices (called “exposure devices” hereinafter). Accordingly, advances are being made in the reduction of the wavelengths of light emitted from exposure light sources. Gas laser devices are being used as exposure light sources instead of conventional mercury lamps. At present, a KrF excimer laser device that emits ultraviolet light at a wavelength of 248 nm and an ArF excimer laser device that emits ultraviolet light at a wavelength of 193 nm are being used as gas laser devices for exposure.

Immersion exposure, in which the apparent wavelength of an exposure light source is reduced by filling the space between the exposure lens of an exposure device and a wafer with a liquid and changing the refractive index, is being researched as a next-generation exposure technique. In the case where immersion exposure is carried out using an ArF excimer laser device as the exposure light source, the wafer may be irradiated with ultraviolet light at a wavelength of 134 nm within the liquid. This technique is referred to as ArF immersion exposure (or ArF immersion lithography).

The natural oscillation amplitude of a KrF excimer laser device, an ArF excimer laser device, or the like is as wide as 350-400 pm. Accordingly, there are cases where chromatic aberration will occur if a projection lens is used in the exposure device, leading to a drop in the resolution. Accordingly, it is necessary to narrow the spectral bandwidth (spectral width) of the laser beam emitted from the gas laser device until the chromatic aberration reaches a level that can be ignored. In recent years, the spectral width has been narrowed by providing a line narrow module having a line narrowing element (an etalon, a grating, or the like) within the laser resonator of the gas laser device. A laser device that narrows the spectral width in this manner is called a narrow-band laser device.

### SUMMARY

A solid-state laser amplifier according to one aspect of the present disclosure is a solid-state laser amplifier that is used with at least one master oscillator configured to output seed laser light and that is configured to amplify the seed laser light, and may include: a first amplifying module including a first optical system having two focusing optical systems disposed so that the focal points of the two focusing optical systems essentially match at a first position, and a first solid-state laser element, located near the first position, disposed so that a surface into which laser light enters is tilted at essentially a Brewster's angle relative to an optical path of the laser light; and a second amplifying module including a second optical system having two focusing optical systems disposed so that the focal points of the two focusing optical systems essentially match at a second position, and a second solid-state laser element, located near the second position, disposed so that a surface into which laser light that has passed through the first amplifying module enters is tilted at essentially a Brewster's angle relative to an optical path of the laser light, and disposed so that a second plane of incidence of the second solid-state laser device into which the laser light enters is rotated, in a rotation direction central to the optical path, relative to a first plane of incidence of the first solid-state laser element into which the laser light enters.

A laser light amplifier according to another aspect of the present disclosure may include: at least one master oscillator configured to output seed light; at least one pumping laser configured to output pumping laser light; the aforementioned solid-state laser amplifier; a first dichroic mirror, disposed between the first solid-state laser element and the at least one pumping laser, configured to reflect the seed light and transmit the pumping laser light; and a second dichroic mirror, disposed between the second solid-state laser element and the at least one pumping laser, configured to reflect the seed light and transmit the pumping laser light.

A solid-state laser device according to another aspect of the present disclosure may include: the aforementioned solid-state laser amplifier; a master oscillator configured to output the laser light to be inputted into the amplifier; and a wavelength converter configured to convert the wavelength of the amplified laser light outputted from the amplifier.

A laser device according to another aspect of the present disclosure may include the aforementioned solid-state laser device and an amplifying apparatus that amplifies laser light outputted from the solid-state laser device.

### BRIEF DESCRIPTION OF THE DRAWINGS

Exemplary embodiments of the present disclosure will be described hereinafter with reference to the appended drawings.

FIG. 1 schematically illustrates an example of the configuration of a laser device according to a first embodiment.

FIG. 2 schematically illustrates an example of the configuration of a solid-state laser device illustrated in FIG. 1.

FIG. 3 schematically illustrates the configuration of an amplifier illustrated in FIG. 2.

FIG. 4 illustrates a positional relationship between two titanium sapphire crystals shown in FIG. 3.

FIG. 5 illustrates a positional relationship between two titanium sapphire crystals in the case where an optical path shown in FIG. 4 has been converted to a straight line.

FIG. 6 schematically illustrates the configuration of an amplifier according to a second embodiment of the present disclosure.

FIG. 7 illustrates a relationship between two titanium sapphire crystals shown in FIG. 6 and a polarization direction of pulsed laser light.

FIG. 8 illustrates a relationship between two titanium sapphire crystals and a polarization direction of pulsed laser light in the case where an optical path shown in FIG. 7 has been converted to a straight line.

FIG. 9 schematically illustrates the configuration of an amplifier according to a third embodiment of the present disclosure.

FIG. 10 schematically illustrates the configuration of an amplifier according to a fourth embodiment of the present disclosure.

FIG. 11 schematically illustrates the configuration of an amplifier according to a fifth embodiment of the present disclosure.

FIG. 12 schematically illustrates the overall configuration of an amplifying apparatus configured as a power amplifier.

FIG. 13 schematically illustrates the overall configuration of an amplifying apparatus that employs a power oscillator including a Fabry-Perot resonator.

FIG. 14 schematically illustrate the overall configuration of an amplifying apparatus that employs a power oscillator including a ring resonator.

FIG. 15 is a top view of the amplifying apparatus illustrated in FIG. 14.

### DETAILED DESCRIPTION

Embodiments of the present disclosure will be described in detail hereinafter with reference to the drawings. The embodiments described hereinafter indicate examples of the present disclosure, and are not intended to limit the content of the present disclosure. Furthermore, not all of the configurations and operations described in the embodiments are required configurations and operations in the present disclosure. Note that identical constituent elements will be given identical reference numerals, and redundant descriptions thereof will be omitted.

The following descriptions will be given according to the order of contents indicated below.

### Contents

### 1. Outline

### 2. Explanation of Terms

### 3. Excimer Laser Device (First Embodiment)

### 3.1 Solid-state Laser Device

### 3.1.1 Amplifier

### 3.1.1.1 First Amplifying Module

### 3.1.1.2 Second Amplifying Module

3.1.1.3 Positional Relationship between Two Titanium Sapphire Crystals

### 4. Variations on Amplifier

### 4.1 Amplifier Capable of Rotating Polarization Direction (Second Embodiment)

4.1.1 Relationship between Two Titanium Sapphire Crystals and Polarization Direction of Pulsed Laser Light

### 4.2 Two-Pass Folding Amplifier (Third Embodiment)

### 4.3 Two-Pass Ring Amplifier (Fourth Embodiment)

### 4.4 Dual-Stage Amplifier (Fifth Embodiment)

### 5. Other

### 5.1 Amplifying Apparatus

### 5.1.1 Power Amp Using Excimer Gas as Gain Medium

### 5.1.2 Power Oscillator Using Excimer Gas as Gain Medium

### 5.1.2.1 Embodiment Including Fabry-Perot Resonator

### 5.1.2.2 Embodiment Including Ring Resonator

### 1. Outline

In a high-output titanium sapphire laser amplifier (called simply a “laser device” hereinafter) capable of operating at a high repetition rate of 1 kHz or more, a laser crystal cut to a Brewster's angle (also called a “Brewster-cut crystal”) may be disposed near the focal point of a focusing optical system disposed confocally. This crystal will be described in further detail. The crystal may be processed so that two counterpart surfaces on the crystal meet both of the following two conditions. The first condition is that the stated two surfaces are planes that are approximately parallel to each other. The second condition is that the two surfaces are angled at a predetermined angle (for example, a Brewster's angle) relative to an imaginary straight line that passes through the center of the stated two surfaces. The crystal may be disposed so that laser light that enters into one of the stated two surfaces advances into the crystal essentially along the stated imaginary straight line and exits from the other of the two surfaces. The embodiments described below employ the stated disposition. In this case, for example, the reflectance of entering linearly-polarized light that is parallel to the plane of incidence of the crystal is low. Laser light outputted from a master oscillator can be amplified by passing, while being focused, through a laser crystal that has been pumped by focusing pumping light from a pumping laser. In the present specification, a Brewster-cut crystal will be described as an example. However, the laser crystal (for example, a titanium sapphire laser amplifier) does not necessarily need to be a Brewster-cut crystal. The embodiments described in the present specification can be realized even if the crystal has a cut aside from a Brewster cut.

However, there are cases where, in a Brewster-cut crystal, the cross-section of the pumping light beam takes on an oval shape. This occurs due to the optical path of the laser light entering into the crystal not being orthogonal to the surface through which the laser light enters. For example, if the beam profile orthogonal to the optical path of the laser light is essentially circular, the beam profile on the surface of the crystal into which the laser light enters will be essentially circular. There are cases, within the crystal, where the energy concentration of the laser light is higher in the minor axis direction of the oval than in the major axis direction. In this case, the focal distance of a thermal lens effect produced in the crystal may differ between the minor axis direction (this is taken as an X direction) and the major axis direction perpendicular to the X direction (this is taken as a Y direction). If the focal distance of the thermal lens effect differs between the X direction and the Y direction, there are cases where astigmatism will be imparted on the amplified laser light. In such a case, the beam profile of the amplified laser light can become non-uniform.

Accordingly, in the following embodiments, two amplification modules in which Brewster-cut crystals are disposed near the focal point of a focusing optical system disposed confocally may be used. The two Brewster-cut crystals may rotate in a rotation direction in which the laser light entry surfaces of the respective crystals are centered on the optical paths of the laser light from outside of the crystals. Through this, a multiplicative effect between a focal distance difference produced by a thermal lens effect occurring in one of the Brewster-cut crystals and a focal distance difference produced by a thermal lens effect occurring in the other titanium sapphire crystal can be reduced. As a result, the beam profile of the amplified laser light can be brought closer to being uniform, as compared to a case in which the directions of eccentricities of the oval-shaped thermal lens effects occurring in the respective two Brewster-cut crystals are the same.

### 2. Terms

Next, terms used in the present disclosure will be defined. “Upstream” refers to a side that is closer to a light source along an optical path of laser light. Likewise, “downstream” refers to a side that is closer to an exposure device along the optical path of laser light. “Prism” refers to an element, having a triangular column shape or a shape similar thereto, through which light including laser light can pass. It is assumed that the base surface and the top surface of the prism are triangular or a shape similar thereto. The three surfaces of the prism that intersect with the base surface and the top surface at approximately 90° are referred to as side surfaces. In the case of a right-angle prism, the surface that does not intersect with the other two of the side surfaces at 90° is referred to as a sloped surface. Note that a prism whose shape has been changed by shaving the apex of the prism or the like can also be included as a prism in the present descriptions. “Optical path” may be an axis that follows the direction of travel of the laser light and passes through approximately the center of a cross-section of the laser light beam.

In the present disclosure, the direction in which laser light travels is defined as a Z direction. Likewise, a direction that is perpendicular to the Z direction is defined as an X direction, and a direction that is perpendicular to both the X direction and the Z direction is defined as a Y direction. Although the direction in which laser light travels is the Z direction, there are cases, in the descriptions, where the X direction and the Y direction change depending on the position of the laser light being discussed. For example, in the case where the direction in which laser light travels (the Z direction) has changed within the X-Z plane, the orientation of the X direction changes after the change in the direction of travel in accordance with that change in the direction of travel, but the Y direction does not change. On the other hand, in the case where the direction in which laser light travels (the Z direction) has changed within the Y-Z plane, the orientation of the Y direction changes after the change in the direction of travel in accordance with that change in the direction of travel, but the X direction does not change. Note that in order to facilitate understanding, in the drawings, coordinate systems are shown as appropriate for laser light that enters into the optical element located furthest upstream among the illustrated optical elements and for laser light emitted from the optical element located furthest downstream among the illustrated optical elements. Coordinate systems for laser light that enters into other optical elements are also illustrated as necessary.

With respect to a reflective optical element, assuming that a surface including both the optical path of the laser light that enters into the optical element and the optical path of the laser light reflected by that optical element is a plane of incidence, “S-polarized light” may be light polarized in a direction perpendicular to the plane of incidence. On the other hand, “P-polarized light” may be light polarized in a direction orthogonal to the optical path and parallel to the plane of incidence.

### 3. Excimer Laser Device

### First Embodiment

A laser device according to a first embodiment of the present disclosure will be described in detail hereinafter with reference to the drawings.

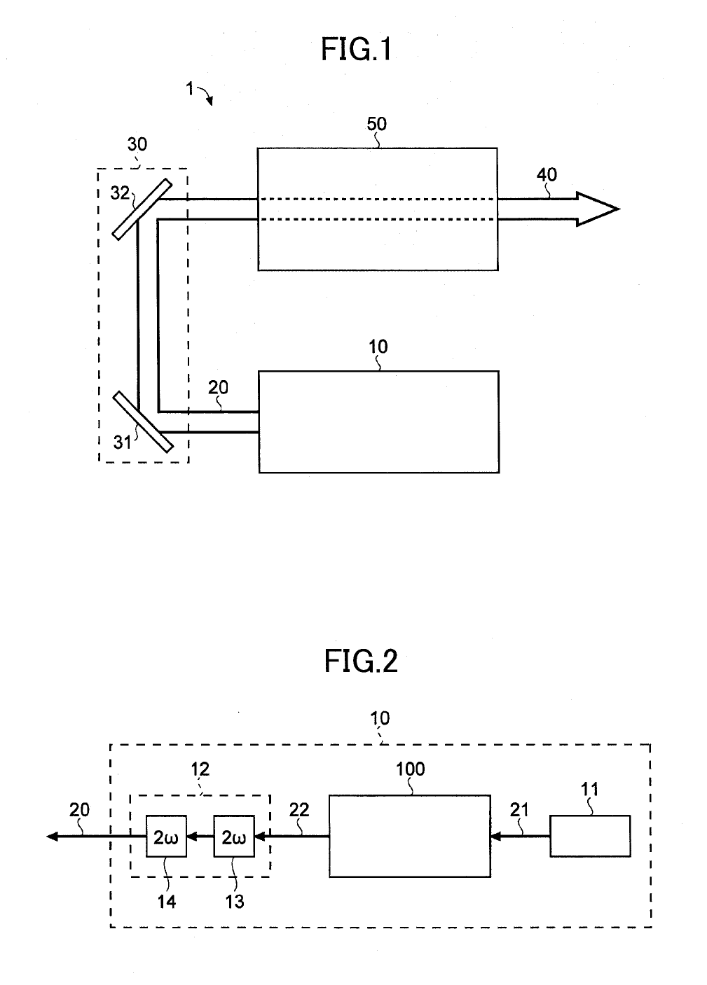

FIG. 1 schematically illustrates an example of the configuration of the laser device according to the first embodiment. A laser device 1 may be a laser used for semiconductor exposure. The laser device 1 may be a laser device that outputs ultraviolet laser light. The laser device 1 may be an ultraviolet laser device that outputs laser light at a wavelength band of, for example, 248.4 nm (for KrF) or 193.4 nm (for ArF). The laser device 1 may be a two-stage laser device including an oscillation stage (master oscillator) and an amplification stage (amplifying apparatus). This laser device 1 may be capable of changing the spectral bandwidth of outputted pulsed laser light.

As shown in FIG. 1, the laser device 1 may include a solid-state laser device 10, an amplifying apparatus 50, and an optical system 30. The solid-state laser device 10 may output pulsed laser light 20. The optical system 30 may lead the pulsed laser light 20 outputted from the solid-state laser device 10 to the amplifying apparatus 50. The amplifying apparatus 50 may amplify the inputted pulsed laser light 20 and output that light as pulsed laser light 40. The outputted pulsed laser light 40 may be inputted into, for example, an exposure device.

### 3.1 Solid-state Laser Device

FIG. 2 schematically illustrates an example of the configuration of the solid-state laser device illustrated in FIG. 1. As shown in FIG. 2, the solid-state laser device 10 may include a master oscillator 11, an amplifier 100, and a wavelength converter 12. The master oscillator 11 may output pulsed laser light (seed light) 21 at a wavelength of, for example, 773.6 nm.

The pulsed laser light 21 outputted from the master oscillator 11 may be inputted into the amplifier 100. The amplifier 100 may be a solid-state laser amplifier that includes a titanium sapphire crystal. The amplifier 100 may amplify the inputted pulsed laser light 21 and output that light as pulsed laser light 22. A specific example of the amplifier 100 will be explained later.

The wavelength converter 12 may convert the inputted pulsed laser light 22 into pulsed laser light 20 in an ultraviolet wavelength band. This wavelength converter 12 may include multiple nonlinear optical crystals 13 and 14.

In the case where the wavelength converter 12 is applied in an ArF excimer laser, the nonlinear optical crystal 13 may be, for example, an LBO crystal. The nonlinear optical crystal 14 may be, for example, a KBBF crystal. Note that a BBO crystal or the like may be used as the nonlinear optical crystal 13 rather than an LBO crystal. The nonlinear optical crystal 13 may emit a second harmonic light (at a wavelength of 386.8 nm) using the entering pulsed laser light 22 (a wavelength of 773.6 nm) as its fundamental harmonic. The nonlinear optical crystal 14 may emit a fourth harmonic light (at a wavelength of 193.4 nm) using the second harmonic light emitted by the nonlinear optical crystal 13 as its fundamental harmonic. This fourth harmonic light may be outputted as the pulsed laser light 20.

Meanwhile, in the case where the wavelength converter 12 is applied in a KrF excimer laser, the nonlinear optical crystal 13 may be, for example, an LBO crystal. The nonlinear optical crystal 14 may be, for example, a BBO crystal. Note that a BBO crystal, a CLBO crystal, or the like may be used as the nonlinear optical crystal 13 rather than an LBO crystal. In addition, a CLBO crystal or the like may be used as the nonlinear optical crystal 14 rather than a BBO crystal. The nonlinear optical crystal 13 may emit a second harmonic light (at a wavelength of 386.8 nm) using the entering pulsed laser light 22 (a wavelength of 773.6 nm) as its fundamental harmonic. The nonlinear optical crystal 14 may emit a third harmonic light (at a wavelength of 248.4 nm) using the second harmonic light emitted by the nonlinear optical crystal 13 as its fundamental harmonic. This third harmonic light may be outputted as the pulsed laser light 20.

### 3.1.1 Amplifier

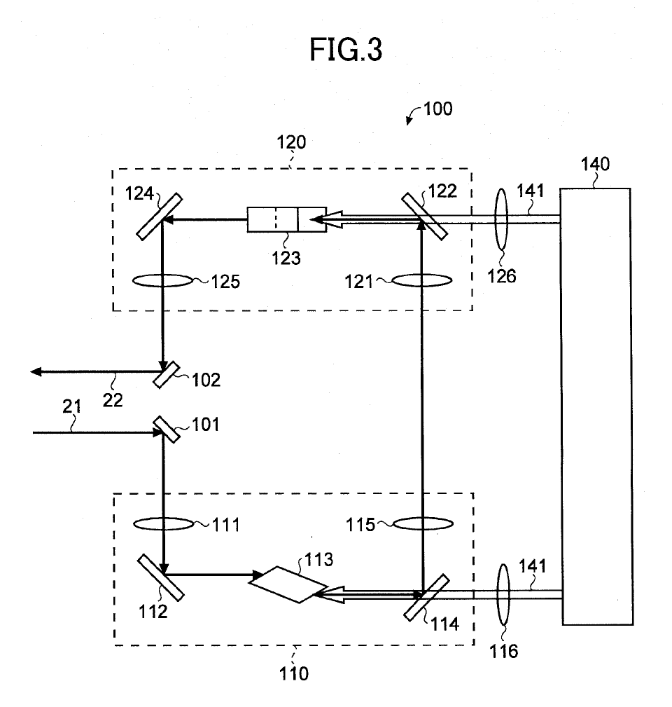

Next, the amplifier 100 in the solid-state laser device 10 will be described using a specific example. FIG. 3 schematically illustrates the configuration of the amplifier 100. As shown in FIG. 3, the amplifier 100 may include a first amplifying module 110, a second amplifying module 120, a pumping laser 140, high-reflecting mirrors 101 and 102, and collimate lenses 116 and 126. The pulsed laser light 21 outputted from the master oscillator 11 may be reflected by the high-reflecting mirror 101 and enter into the first amplifying module 110. Note that the pumping laser 140 may be configured of two pumping lasers 140a and 140b, not shown, or may be configured of a single pumping laser. The output laser light from the two pumping lasers 140a and 140b may be focused by the collimate lenses 116 and 126, respectively. In the case where there is only a single pumping laser, the output laser light from that laser may be split into two by a beam splitter (not shown), and each resulting laser light may be focused by the collimate lenses 116 and 126, respectively.

### 3.1.1.1 First Amplifying Module

Here, the configuration of the first amplifying module 110 will be described. As shown in FIG. 3, the first amplifying module 110 may include a focusing optical system 111, a high-reflecting mirror 112, a titanium sapphire crystal 113, a dichroic mirror 114, and a focusing optical system 115. At least the focusing optical system 111 and the focusing optical system 115 are referred to as a first optical system. The same applies in the drawings described hereinafter as well. The dichroic mirror 114 may highly reflect the pulsed laser light 21 while highly transmitting pumping light 141.

The focusing optical systems 111 and 115 may each be transmissive optical elements such as lenses, may be reflective optical elements such as mirrors, or may be a combination thereof. The focusing optical system 111 may form a focal point via the high-reflecting mirror 112. The focusing optical system 115 may form a focal point via the dichroic mirror 114. The focal position of the focusing optical system 111 and the focal position of the focusing optical system 115 may essentially match. In other words, the focusing optical system 111 and the focusing optical system 115 may be disposed in an essentially confocal positional relationship. The titanium sapphire crystal 113 may be disposed at the essentially matching focal positions of the focusing optical systems 111 and 115 (a first position). However, the position of the titanium sapphire crystal 113 need not perfectly match the focal positions of the focusing optical systems 111 and 115.

The titanium sapphire crystal 113 may be disposed so that the surface thereof that opposes the optical path of the pulsed laser light 21 is sloped at a Brewster's angle relative to that optical path. The laser light that enters into the titanium sapphire crystal 113 from one of the Brewster-cut surfaces can exit from the other Brewster-cut surface. The pumping light 141 outputted from the pumping laser 140 may enter into the titanium sapphire crystal 113. The surface of the titanium sapphire crystal 113 into which the pumping light 141 enters may be sloped at a Brewster's angle relative to the optical path of the pumping light 141.

The pulsed laser light 21 outputted from the master oscillator 11 may first be reflected by the high-reflecting mirror 101. The pulsed laser light 21 reflected by the high-reflecting mirror 101 may then enter into the focusing optical system 111 of the first amplifying module 110. The pulsed laser light 21 that passes through the focusing optical system 111 may enter into the titanium sapphire crystal 113 after being reflected by the high-reflecting mirror 112. At this time, the pulsed laser light 21 may form a focal point immediately prior to entering into the titanium sapphire crystal 113, or may form a focal point within the titanium sapphire crystal 113.

The pumping light 141 outputted from the pumping laser 140 may enter into the titanium sapphire crystal 113 via the dichroic mirror 114 after being converted into parallel light by the collimate lens 116. At this time, the pumping light 141 may enter into the titanium sapphire crystal 113 along, for example, essentially the same optical path as the optical path of the amplified pulsed laser light 21 emitted from the titanium sapphire crystal 113. Through this, the overlap efficiency of the pumping light 141 and the pulsed laser light 21 is improved within the titanium sapphire crystal 113, and thus the amplification efficiency of the pulsed laser light 21 can be improved. In addition, because the number of mirrors for leading the pumping light 141 into the titanium sapphire crystals 113 and 123 can be reduced, the configuration of the device can be simplified, which makes it possible to improve the stability of the amplified pulsed laser light 21. However, the pumping light 141 may enter into the titanium sapphire crystal 113 from the side of the titanium sapphire crystal 113 on which the pulsed laser light 21 enters, instead of the side from which the pulsed laser light 21 exits.

The amplified pulsed laser light 21 emitted from the titanium sapphire crystal 113 may be reflected by the dichroic mirror 114 while expanding. The pulsed laser light 21 reflected by the dichroic mirror 114 may enter into the focusing optical system 115. The focusing optical system 115 may convert the entering pulsed laser light 21 into parallel light. The pulsed laser light 21 converted into parallel light may then enter into the second amplifying module 120.

### 3.1.1.2 Second Amplifying Module

Next, the configuration of the second amplifying module 120 will be described. As shown in FIG. 3, the second amplifying module 120 may have essentially the same configuration as the first amplifying module 110. Specifically, the second amplifying module 120 may include a focusing optical system 121, a dichroic mirror 122, the titanium sapphire crystal 123, a high-reflecting mirror 124, and a focusing optical system 125. At least the focusing optical system 121 and the focusing optical system 125 are referred to as a second optical system. The same applies in the drawings described hereinafter as well.

The focusing optical systems 121 and 125 may be the same as the focusing optical system 111 or 115, respectively. The focusing optical system 121 may form a focal point via the dichroic mirror 122. The focusing optical system 125 may form a focal point via the high-reflecting mirror 124. The focal position of the focusing optical system 121 and the focal position of the focusing optical system 125 may essentially match. In other words, the focusing optical system 121 and the focusing optical system 125 may be disposed in an essentially confocal positional relationship. The titanium sapphire crystal 123 may be disposed at the essentially matching focal positions of the focusing optical systems 121 and 125 (a second position). However, the position of the titanium sapphire crystal 123 need not perfectly match the focal positions of the focusing optical systems 121 and 125.

The titanium sapphire crystal 123 may be disposed so that the surface thereof that opposes the optical path of the pulsed laser light 21 is sloped at a Brewster's angle relative to that optical path. The pumping light 141 outputted from the pumping laser 140 may enter into the titanium sapphire crystal 123. The surface of the titanium sapphire crystal 123 into which the pumping light 141 enters may be sloped at a Brewster's angle relative to the optical path of the pumping light 141.

The pulsed laser light 21 emitted from the first amplifying module 110 may first enter into the focusing optical system 121 of the second amplifying module 120. The pulsed laser light 21 that passes through the focusing optical system 121 may enter into the titanium sapphire crystal 123 after being reflected by the dichroic mirror 122. At this time, the pulsed laser light 21 may form a focal point immediately prior to entering into the titanium sapphire crystal 123, or may form a focal point within the titanium sapphire crystal 123.

The pumping light 141 outputted from the pumping laser may enter into the titanium sapphire crystal 123 via the dichroic mirror 122 after being converted into parallel light by the collimate lens 126. At this time, the pumping light 141 may enter into the titanium sapphire crystal 123 along, for example, essentially the same optical path as the optical path of the amplified pulsed laser light 21 that enters into the titanium sapphire crystal 123. Through this, the overlap efficiency of the pumping light 141 and the pulsed laser light 21 is improved within the titanium sapphire crystal 123, and thus the amplification efficiency of the pulsed laser light 21 can be improved. However, the pumping light 141 may enter into the titanium sapphire crystal 123 from the side of the titanium sapphire crystal 123 from which the pulsed laser light 21 exits, instead of the side on which the pulsed laser light 21 enters.

The amplified pulsed laser light 21 emitted from the titanium sapphire crystal 123 may be reflected by the high-reflecting mirror 124 while expanding. The pulsed laser light 21 reflected by the high-reflecting mirror 124 may enter into the focusing optical system 125. The focusing optical system 125 may convert the entering pulsed laser light 21 into parallel light. The pulsed laser light 21 converted into parallel light may then be outputted from the amplifier 100 via a high-reflecting mirror (output mirror) 102 as the pulsed laser light 22.

3.1.1.3 Positional Relationship between Two Titanium Sapphire Crystals

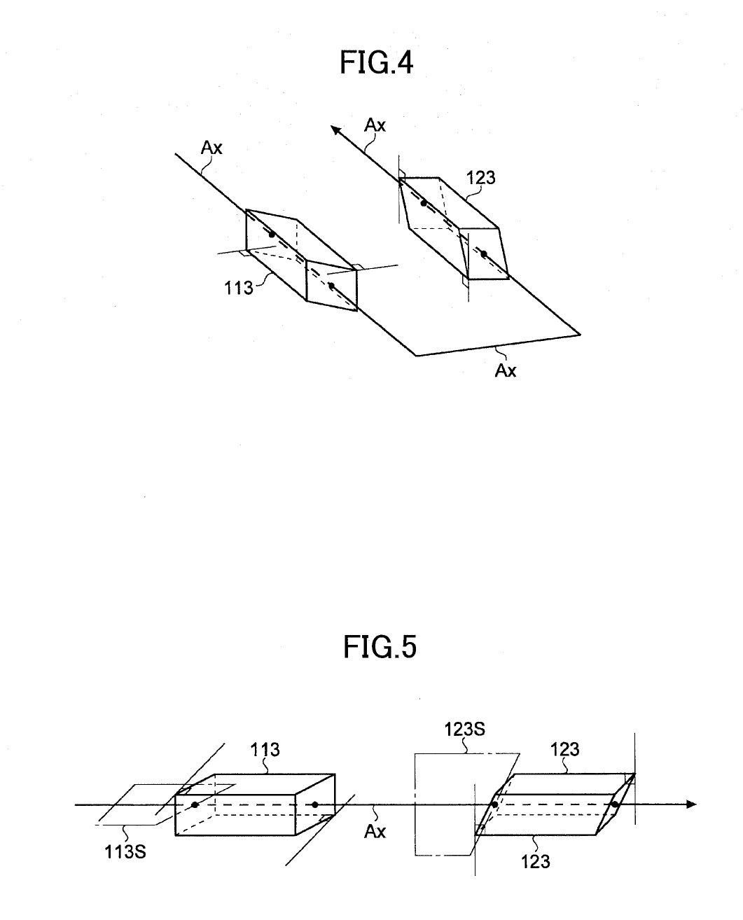

Here, a positional relationship between the two titanium sapphire crystals 113 and 123 will be described. FIG. 4 illustrates a positional relationship between the two titanium sapphire crystals 113 and 123 shown in FIG. 3. Ax indicates the optical path of the pulsed laser light 21. FIG. 5, meanwhile, illustrates a positional relationship between the two titanium sapphire crystals 113 and 123 in the case where the optical path Ax shown in FIG. 4 has been converted to a straight line.

As shown in FIG. 4, the orientation of the titanium sapphire crystal 123 relative to the optical path Ax of the pulsed laser light 21 may be rotated, in a rotation direction central to the optical path Ax, relative to the orientation of the titanium sapphire crystal 113 relative to the optical path Ax of the pulsed laser light 21. In this case, if it is then assumed that, as shown in FIG. 5, the optical path Ax of the pulsed laser light 21 has been converted to a straight line between the titanium sapphire crystal 113 and the titanium sapphire crystal 123, a plane of incidence 123S at which the pulsed laser light 21 enters into the titanium sapphire crystal 123 can be rotated, in a rotation direction central to the optical path Ax, relative to a plane of incidence 113S at which the pulsed laser light 21 enters into the titanium sapphire crystal 113. Note that the optical path Ax of the pulsed laser light 21 being converted to a straight line between the titanium sapphire crystal 113 and the titanium sapphire crystal 123 may refer to extending the bent optical path Ax of the pulsed laser light 21 into a straight line while preventing the beam cross-section of the pulsed laser light 21, the polarization direction thereof, and so on from rotating central to the optical path Ax.

Through the disposition described above, the direction of eccentricity of the oval-shaped thermal lens effect produced in the one titanium sapphire crystal 123 can rotate approximately 90° in a rotation direction central to the optical path Ax of the pulsed laser light 21 relative to the direction of eccentricity of the oval-shaped thermal lens effect produced in the other titanium sapphire crystal 113. Through this, a multiplicative effect between a focal distance difference produced by the thermal lens effect occurring in the titanium sapphire crystal 113 and a focal distance difference produced by the thermal lens effect occurring in the titanium sapphire crystal 123 can be reduced. As a result, the beam profile of the amplified pulsed laser light 22 can be brought closer to being uniform, as compared to a case in which the directions of eccentricities of the oval-shaped thermal lens effects occurring in the respective two titanium sapphire crystals 113 and 123 are the same. Note that the direction of eccentricity may refer to the direction of a straight line that connects two focal points in the same oval.

It is preferable for the amount by which the titanium sapphire crystal 123 rotates relative to the titanium sapphire crystal 113 to be, for example, greater than 45° and less than 135°. In this case, the focal distance difference produced by the thermal lens effect occurring in the titanium sapphire crystal 113 and the focal distance difference produced by the thermal lens effect occurring in the titanium sapphire crystal 123 can be reduced. As a result, the beam profile of the amplified pulsed laser light 22 can be brought even closer to being uniform.

Furthermore, it is preferable for the amount by which the titanium sapphire crystal 123 rotates relative to the titanium sapphire crystal 113 to be, for example, 90°. In this case, the focal distance difference produced by the thermal lens effect occurring in the titanium sapphire crystal 113 can be eliminated by the focal distance difference produced by the thermal lens effect occurring in the titanium sapphire crystal 123. As a result, the beam profile of the amplified pulsed laser light 22 can be brought even closer to being essentially uniform.

### 4. Variations on Amplifier

Next, other embodiments of the stated amplifier in the solid-state laser device 10 of the laser device 1 will be described using several examples. Note that in the following descriptions, configurations aside from the amplifier in the solid-state laser device 10 may be the same as those in the aforementioned first embodiment.

### 4.1 Amplifier Capable of Rotating Polarization Direction

### Second Embodiment

In the second embodiment, an amplifier in which the polarization direction of the pulsed laser light 21 can be rotated in accordance with the plane of incidence of the titanium sapphire crystal into which the pulsed laser light 21 enters will be given as an example.

When an electromagnetic plane wave enters at a border surface between media having different refractive indexes, P-polarized light has a higher transmissibility than S-polarized light. Accordingly, with an amplifier that uses a titanium sapphire crystal, which is a transmissive optical element, the component of the pulsed laser light 21 that enters the Brewster-cut surface of the titanium sapphire crystal as P-polarized light is more easily transmitted within the crystal than the component that enters as S-polarized light. Accordingly, in the second embodiment, the polarization direction of the pulsed laser light 21 may be rotated in accordance with the orientation of the Brewster-cut surfaces of the titanium sapphire crystals 113 and 123. Through this, the efficiency with which the pulsed laser light 21 passes into the titanium sapphire crystals 113 and 123 can be increased. Asa result, the optical intensity of the amplified pulsed laser light 22 can be increased.

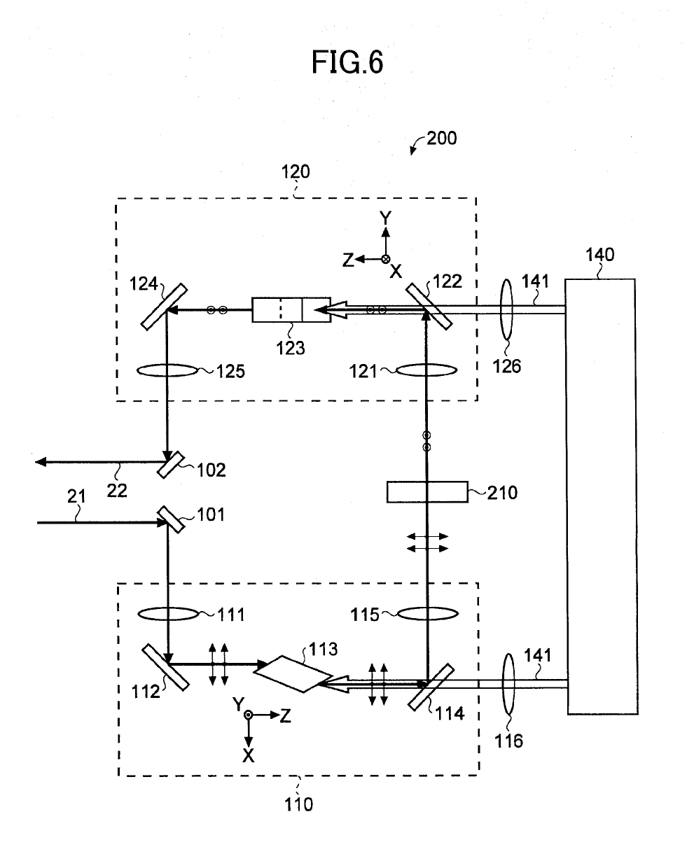

FIG. 6 schematically illustrates the configuration of an amplifier 200 according to the second embodiment. As shown in FIG. 6, the amplifier 200 may include a first optical retarder 210 in addition to the same configuration as the amplifier 100 shown in FIG. 3. The optical retarder may be a half-wave plate. The optical retarder 210 may rotate the polarization direction of the pulsed laser light 21 in a rotation direction central to the optical path Ax of the pulsed laser light 21. The optical retarder 210 may be disposed in the optical path of the pulsed laser light 21 between the first amplifying module 110 and the second amplifying module 120. However, the disposition is not limited thereto, and the optical retarder 210 may be disposed in any optical path between the titanium sapphire crystal 113 in the first amplifying module 110 and the titanium sapphire crystal 123 in the second amplifying module 120.

4.1.1 Relationship between Two Titanium Sapphire Crystals and Polarization Direction of Pulsed Laser Light

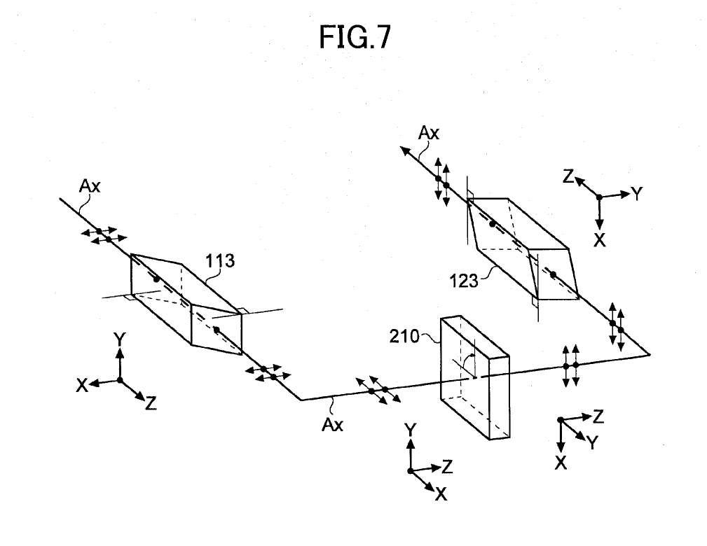

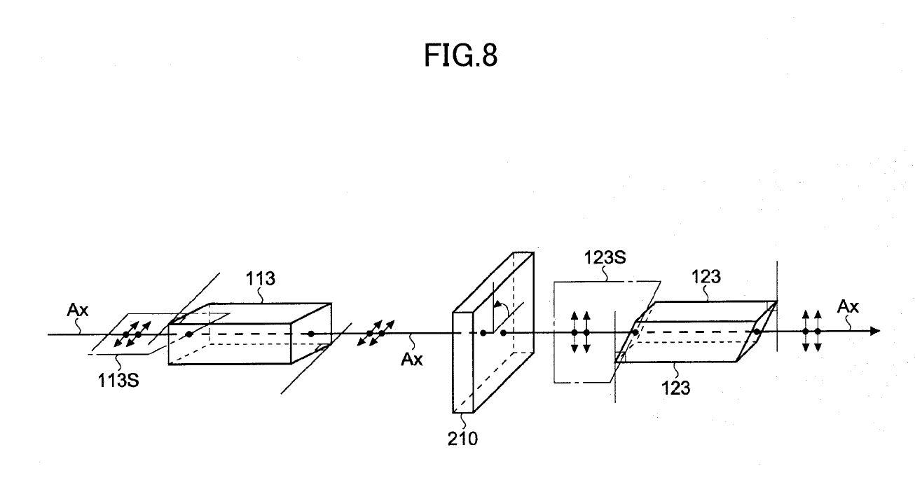

Here, a relationship between the two titanium sapphire crystals 113 and 123 and the polarization direction of the pulsed laser light 21 will be described. FIG. 7 illustrates a relationship between the two titanium sapphire crystals 113 and 123 and the polarization direction of the pulsed laser light 21 shown in FIG. 6. FIG. 8, meanwhile, illustrates a relationship between the two titanium sapphire crystals 113 and 123 and the polarization direction of the pulsed laser light 21 in the case where the optical path Ax shown in FIG. 7 has been converted to a straight line. Note that the following describes an example in which P-polarized pulsed laser light 21 has entered into the upstream titanium sapphire crystal 113. The arrows in the optical path Ax in FIGS. 7 and 8 indicate the P-polarization direction of the pulsed laser light 21.

As shown in FIG. 7, the optical retarder 210 may rotate the polarization direction of the pulsed laser light 21 in a rotation direction central to the optical path Ax of the pulsed laser light 21. In this case, assuming, as shown in FIG. 8, that the optical path Ax of the pulsed laser light 21 extending from the titanium sapphire crystal 113, through the optical retarder 210, and to the titanium sapphire crystal 123 has been converted into a straight line, the polarization direction of the pulsed laser light 21 on the titanium sapphire crystal 123 is rotated, in a rotation direction central to the optical path Ax, relative to the polarization direction of the pulsed laser light 21 on the titanium sapphire crystal 113. Note that the optical path Ax of the pulsed laser light 21 extending from the titanium sapphire crystal 113, through the optical retarder 210, and to the titanium sapphire crystal 123 being converted into a straight line may refer to extending the bent optical path Ax of the pulsed laser light 21 into a straight line while ensuring that the beam cross-section of the pulsed laser light 21 does not rotate central to the optical path Ax and ensuring that the polarization direction of the pulsed laser light 21 is not influenced by rotational effects a side from those applied by the optical retarder 210.

The rotational amount of the polarization direction may be the same as the amount by which the titanium sapphire crystal 123 rotates relative to the titanium sapphire crystal 113. In the case where the amount by which the titanium sapphire crystal 123 rotates relative to the titanium sapphire crystal 113 is 90°, the rotational amount of the polarization direction may also be 90°. At this time, adjusting so that the pulsed laser light 21 enters into both the titanium sapphire crystals 113 and 123 in the P-polarization direction makes it possible to increase the optical intensity of the amplified pulsed laser light 22 even more.

### 4.2 Two-Pass Folding Amplifier

### Third Embodiment

In a third embodiment, an amplifier configured so that the pulsed laser light 21 travels back and forth along the optical path within the amplifier will be given as an example. Although the third embodiment uses a configuration based on the amplifier 200 according to the second embodiment, the embodiment is not limited thereto, and may, for example, be based on the amplifier 100 according to the first embodiment.

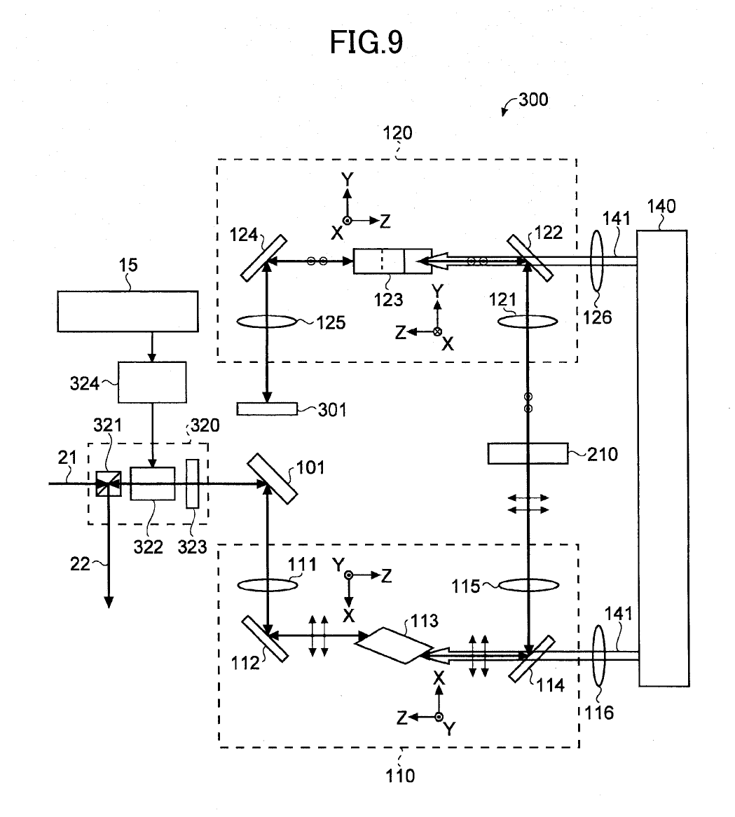

FIG. 9 schematically illustrates the configuration of an amplifier 300 according to the third embodiment. As shown in FIG. 9, the amplifier 300 may include a light entry/exit module 320 in addition to the same configuration as the amplifier 200 shown in FIG. 6. Furthermore, with the amplifier 300, the high-reflecting mirror 102 on the laser output side may be replaced with a folding mirror 301.

The light entry/exit module 320 may include a polarizing beam splitter 321, a polarization direction control element (for example, a Faraday rotator 322), and a third optical retarder 323. The optical retarder may be a half-wave plate. The polarizing beam splitter 321 may reflect S-polarized pulsed laser light 21 and transmit P-polarized pulsed laser light 21. The Faraday rotator 322 may rotate the polarization direction of the transmitted pulsed laser light 21 in accordance with a voltage applied from an external power source 324. In the case where a voltage is not applied to the Faraday rotator 322, the pulsed laser light 21 may pass through the Faraday rotator 322 without its polarization direction being rotated. The power source 324 may apply a voltage to the Faraday rotator 322 under the control of, for example, a control unit 15 that controls the amplifier 300. Note that the Faraday rotator 322 may be replaced with another optical element capable of controlling the polarization direction of the pulsed laser light 21. The optical retarder 323 may rotate the polarization direction of the pulsed laser light 21 in a rotation direction central to the optical path Ax of the pulsed laser light 21.

The pulsed laser light 21 outputted from the master oscillator 11 may first enter into the polarizing beam splitter 321 of the light entry/exit module 320. The polarizing beam splitter 321 may transmit primarily the P-polarized component of the entering pulsed laser light 21. Note that the pulsed laser light 21 outputted from the master oscillator 11 may be P-polarized light on the polarizing beam splitter 321.

The pulsed laser light 21 that has passed through the polarizing beam splitter 321 may enter into the Faraday rotator 322. At this time, a voltage that rotates the polarization direction of the pulsed laser light 21 by 90° may be applied to the Faraday rotator 322. In this case, the pulsed laser light 21 that enters into the Faraday rotator 322 can have its polarization direction rotated 90° and then be emitted from the Faraday rotator 322.

The component of the pulsed laser light 21 that is linearly-polarized in the X direction may pass through the polarizing beam splitter 321 and enter into the Faraday rotator 322. The pulsed laser light 21 that has passed through the Faraday rotator 322 may have its polarization direction rotated 45°, and may then enter into the optical retarder 323. The pulsed laser light 21 may then have its polarization direction rotated to −45° by the optical retarder 323. Through this, the polarization direction of the pulsed laser light 21 can become essentially the same as that of the pulsed laser light 21 prior to passing through the polarizing beam splitter 321 and entering into the Faraday rotator 322.

The pulsed laser light 21 that has passed through the optical retarder 323 may be reflected by the high-reflecting mirror 101 on the input side and enter into the first amplifying module 110. The pulsed laser light 21 that enters into the first amplifying module 110 may enter into the titanium sapphire crystal 113 via the focusing optical system 111 and the high-reflecting mirror 112. At this time, it is preferable for the pulsed laser light 21 to enter into the titanium sapphire crystal 113 as P-polarized light. This is made possible by adjusting the orientations of the polarizing beam splitter 321 and the titanium sapphire crystal 113.

The pumping light 141 may enter into the titanium sapphire crystal 113 via the collimate lens 116 and the dichroic mirror 114. Through this, the pulsed laser light 21 can be amplified within the titanium sapphire crystal 113. The amplified pulsed laser light 21 that is emitted from the titanium sapphire crystal 113 may enter into the optical retarder 210 via the dichroic mirror 114 and the focusing optical system 115. The optical retarder 210 may rotate the polarization direction of the pulsed laser light 21 in a rotation direction central to the optical path Ax of the pulsed laser light 21.

The pulsed laser light 21 whose polarization direction has been rotated may then enter into the second amplifying module 120. The pulsed laser light 21 that enters into the second amplifying module 120 may enter into the titanium sapphire crystal 123 via the focusing optical system 121 and the dichroic mirror 122. At this time, it is preferable for the pulsed laser light 21 to enter into the titanium sapphire crystal 123 as P-polarized light. This is made possible by adjusting the orientation of the titanium sapphire crystal 123 relative to the titanium sapphire crystal 113 and the amount by which the polarization direction is rotated by the optical retarder 210.

The pumping light 141 may enter into the titanium sapphire crystal 123 via the collimate lens 126 and the dichroic mirror 122. Through this, the pulsed laser light 21 can be amplified within the titanium sapphire crystal 123. The amplified pulsed laser light 21 that is emitted from the titanium sapphire crystal 123 may enter into the folding mirror 301 via the high-reflecting mirror 124 and the focusing optical system 125.

The folding mirror 301 may fold the optical path of the pulsed laser light 21. The pulsed laser light 21 reflected by the folding mirror 301 (called “returning light”) may enter into the light entry/exit module 320 from the high-reflecting mirror 101 by returning along the same optical path as the optical path at which the pulsed laser light 21 enters the mirror 301.

The polarization direction of the returning light may be rotated at −45° by the retarder 323, and may be rotated at a further −45° by the Faraday rotator 322. Through this, the polarization direction of the returning light can be rotated a total of −90° and converted to the Y direction. This returning light may be reflected by the polarizing beam splitter 321 and extracted as the pulsed laser light 22.

The pulsed laser light 21 that has passed through the Faraday rotator 322 may enter into the polarizing beam splitter 321 as S-polarized light. The polarizing beam splitter 321 can reflect the pulsed laser light 21 that has entered as S-polarized light. The pulsed laser light 21 reflected by the polarizing beam splitter 321 may be outputted from the amplifier 300 as the pulsed laser light 22.

Although an example in which a voltage is applied to the Faraday rotator 322 in the case where the pulsed laser light 21 is entered into the amplifier 300 and a voltage is not applied to the Faraday rotator 322 in the case where the pulsed laser light 22 is to be emitted from the amplifier 300 is described here, it should be noted that the embodiment is not limited thereto. For example, a voltage may not be applied to the Faraday rotator 322 in the case where the pulsed laser light 21 is entered into the amplifier 300 and a voltage may be applied to the Faraday rotator 322 in the case where the pulsed laser light 22 is to be emitted from the amplifier 300. Even in such a case, the orientations of the polarizing beam splitter 321 and the titanium sapphire crystal 113 can be adjusted.

### 4.3 Two-Pass Ring Amplifier

### Fourth Embodiment

In a fourth embodiment, an amplifier configured so that the pulsed laser light 21 makes multiple passes (for example, two passes) along the optical path within the amplifier will be given as an example. Although the fourth embodiment uses a configuration based on the amplifier 200 according to the second embodiment, the embodiment is not limited thereto, and may, for example, be based on the amplifier 100 according to the first embodiment.

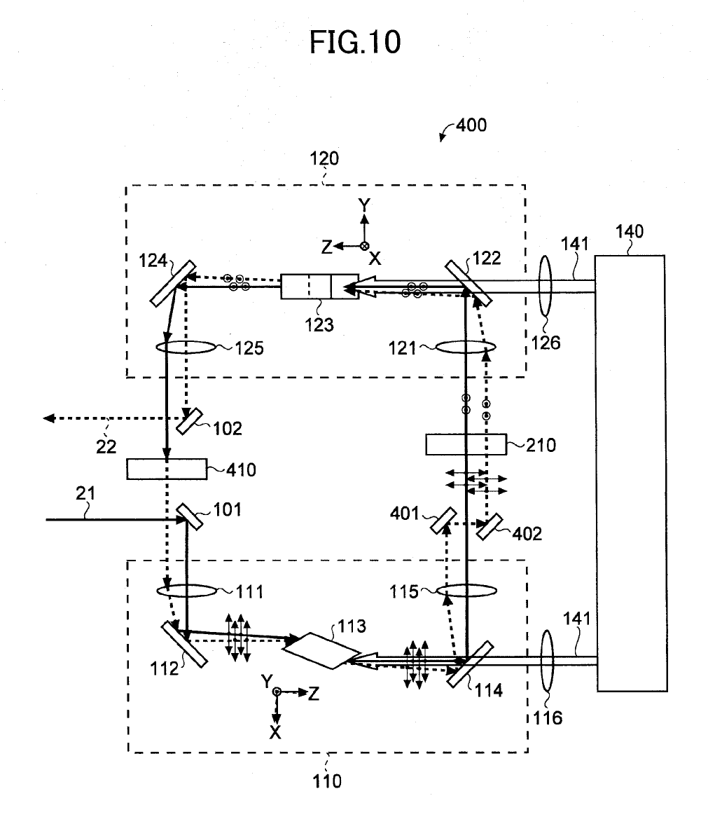

FIG. 10 schematically illustrates the configuration of an amplifier 400 according to the fourth embodiment. As shown in FIG. 10, the amplifier 400 may include two high-reflecting mirrors 401 and 402 and a second optical retarder 410 in addition to the same configuration as the amplifier 200 shown in FIG. 6.

The optical path of the pulsed laser light 21 formed within the amplifier 400 may make two cycles within the amplifier. At this time, the high-reflecting mirror 124 within the second amplifying module 120 may be tilted so that the optical path in the second cycle within the amplifier 400 (the optical path indicated by a broken line in FIG. 10) is shifted from the optical path in the first cycle (the optical path indicated by the solid line in FIG. 10).

The optical retarder 410 may be disposed in a position that is, for example, between the optical path in the first cycle within the amplifier 400 and the optical path in the second cycle. Through this, the polarization direction of the pulsed laser light 21 that enters into the first amplifying module 110 can be made the same in the first cycle and the second cycle.

The high-reflecting mirrors 401 and 402 may be disposed in the optical path in the second cycle within the amplifier 400. For example, the high-reflecting mirrors 401 and 402 may be disposed in the optical path between the first module 110 and the second module in the optical path in the second cycle. The high-reflecting mirrors 401 and 402 may be configured to prevent the optical path in the second cycle for the pulsed laser light 21 from deviating greatly from an optical path in which the laser light can be amplified by the titanium sapphire crystals 113 and 123. With respect to deviation from the optical path caused by the high-reflecting mirror 124, however, note that the high-reflecting mirrors 401 and 402 need not be provided in the case where the optical path of the pulsed laser light 21 in the second cycle does not deviate from the amplifiable optical path.

The pulsed laser light 21 that has passed through the optical path in the second cycle may be outputted from the amplifier 400 as the pulsed laser light 22 by being reflected by the high-reflecting mirror 102.

### 4.4 Dual-Stage Amplifier

### Fifth Embodiment

In a fifth embodiment, an amplifier configured so that the pulsed laser light 21 travels back and forth along an optical path within an amplifying module in a first stage, of the two amplifying modules. Although the fifth embodiment uses a configuration based on the amplifier 200 according to the second embodiment, the embodiment is not limited thereto, and may, for example, be based on the amplifier 100 according to the first embodiment.

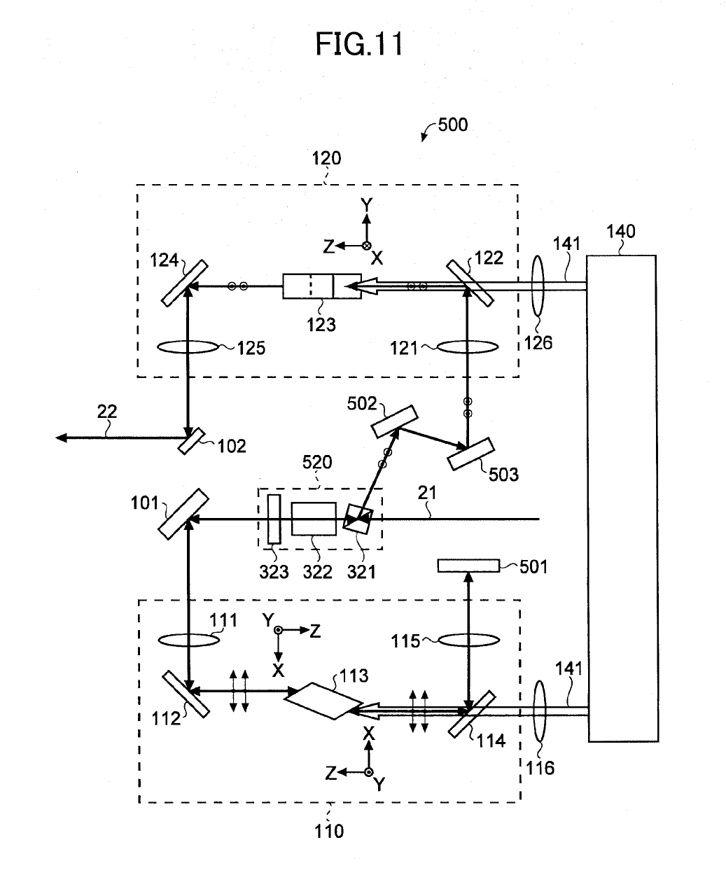

FIG. 11 schematically illustrates the configuration of an amplifier 500 according to the fifth embodiment. As shown in FIG. 11, the amplifier 500 may include a light relay module 520 in addition to the same configuration as the amplifier 200 shown in FIG. 6. In addition, the amplifier 500 may further include a folding mirror 501 and two high-reflecting mirrors 502 and 503.

The light relay module 520 may have a similar configuration as the light entry/exit module 320 illustrated in FIG. 9. However, in the light relay module 520, the polarizing beam splitter 321 may be tilted in the direction of the plane of incidence of the pulsed laser light 21. The embodiment is not limited thereto, however.

The two high-reflecting mirrors 502 and 503 may adjust the optical path of the pulsed laser light 21 that enters into the second amplifying module 120 from the first amplifying module 110 through the light relay module 520.

The pulsed laser light 21 outputted from the master oscillator 11 may first enter into the polarizing beam splitter 321 of the light relay module 520. The polarizing beam splitter 321 may transmit primarily the P-polarized component of the entering pulsed laser light 21. Note that the pulsed laser light 21 outputted from the master oscillator 11 may be P-polarized light on the polarizing beam splitter 321.

The pulsed laser light 21 that has passed through the polarizing beam splitter 321 may pass through Faraday rotator 322 and the optical retarder 323 in that order. At this time, a voltage that rotates the polarization direction of the pulsed laser light 21 by 90° may be applied to the Faraday rotator 322. In this case, the polarization direction of the pulsed laser light 21 that has passed through the Faraday rotator 322 and the optical retarder 323 may be essentially the same as that of the pulsed laser light 21 that has passed through the polarizing beam splitter 321.

The pulsed laser light 21 that has passed through the light relay module 520 may be reflected by the high-reflecting mirror 101 on the input side and enter into the first amplifying module 110. The pulsed laser light 21 that enters into the first amplifying module 110 may enter into the folding mirror 501 through the focusing optical system 111, the high-reflecting mirror 112, the titanium sapphire crystal 113, the dichroic mirror 114, and the focusing optical system 115.

The folding mirror 501 may fold the optical path of the pulsed laser light 21 emitted from the focusing optical system 115 of the first amplifying module 110. The pulsed laser light 21 reflected by the folding mirror 501 may enter into the light relay module 520 from the side of the optical retarder 323 by returning on the same optical path within the first amplifying module 110.

The pulsed laser light 21 that has entered into the light relay module 520 from the side of the optical retarder 323 may enter into the polarizing beam splitter 321 through the optical retarder 323 and the Faraday rotator 322. At this time, a voltage may not be applied to the Faraday rotator 322. In this case, the pulsed laser light 21 that has passed through the optical retarder 323 and the Faraday rotator 322 can have its polarization direction rotated primarily by the optical retarder 323. Accordingly, the pulsed laser light 21 that has passed through the optical retarder 323 and the Faraday rotator 322 can enter into the polarizing beam splitter 321 as S-polarized light.

The polarizing beam splitter 321 can reflect the pulsed laser light 21 that has entered as S-polarized light from the stated direction. The pulsed laser light 21 reflected by the polarizing beam splitter 321 may enter into the second amplifying module 120 through the high-reflecting mirrors 502 and 503. The pulsed laser light 21 that has entered into the second amplifying module 120 may enter into the high-reflecting mirror 102 through the focusing optical system 121, the dichroic mirror 122, the titanium sapphire crystal 123, the high-reflecting mirror 124, and the focusing optical system 125. The pulsed laser light 21 that has entered into the high-reflecting mirror 102 may be outputted from the amplifier 500 by being reflected as the pulsed laser light 22.

### 5. Other

### 5.1 Amplifying Apparatus

Here, several specific examples of the amplifying apparatus 50 in the aforementioned embodiments and shown in FIG. 1 will be given. The amplifying apparatus 50 may be a laser amplifying apparatus of a variety of types, such as a power oscillator, a power amplifier, a regenerative amplifier, or the like. Furthermore, the amplifying apparatus 50 may be a single amplifying apparatus, or may include a plurality of amplifying apparatuses.

### 5.1.1 Power Amplifier Using Excimer Gas as Gain Medium

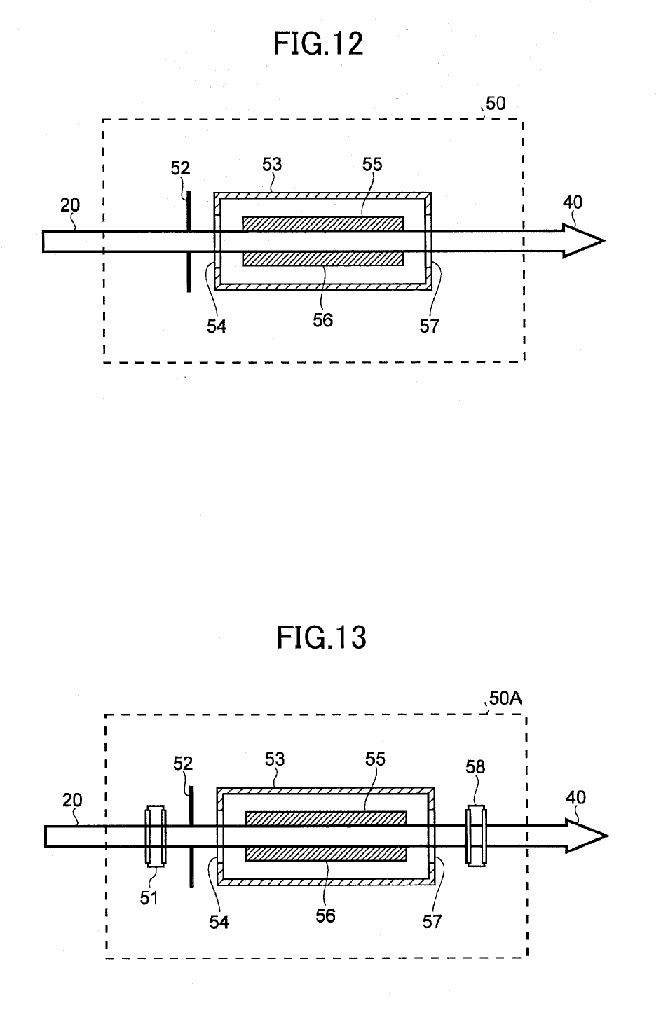

FIG. 12 schematically illustrates the overall configuration of the amplifying apparatus 50 configured as a power amplifier. As shown in FIG. 12, the amplifying apparatus 50 may include a chamber 53. The amplifying apparatus 50 may further include a slit 52 that adjusts the beam profile of the pulsed laser light 20. Windows 54 and 57 may be provided in the chamber 53. The windows 54 and 57 may allow the pulsed laser light 20 to pass through while maintaining the chamber 53 in a sealed state. A gain medium such as an excimer gas may be injected into the chamber 53. The gain medium may contain, for example, one of Kr gas and Ar gas, as well as F₂ gas and Ne, and may further contain an extremely small amount of Xe gas. Furthermore, a pair of discharge electrodes 55 and 56 may be provided within the chamber 53. The discharge electrodes 55 and 56 may be disposed on either side of a region through which the pulsed laser light 20 passes (an amplification region). A pulsed high voltage may be applied between the discharge electrodes 55 and 56, from a power source (not shown). The high voltage may be applied between the discharge electrodes 55 and 56 in correspondence with the timing at which the pulsed laser light 20 passes through the amplification region. When the high voltage is applied between the discharge electrodes 55 and 56, an amplification region containing an activated gain medium can be formed between the discharge electrodes 55 and 56. The pulsed laser light 20 can be amplified when passing through this amplification region.

### 5.1.2 Power Oscillator Using Excimer Gas as Gain Medium

Next, a case where a power oscillator is used as the amplifying apparatus 50 will be described using the following examples.

### 5.1.2.1 Embodiment Including Fabry-Perot Resonator

First, a case where a power oscillator including a Fabry-Perot resonator is used as the amplifying apparatus 50 will be described as an example. FIG. 13 schematically illustrates the overall configuration of an amplifying apparatus 50A that employs a power oscillator including a Fabry-Perot resonator. As shown in FIG. 13, the amplifying apparatus 50A may include, in addition to the same configuration as the amplifying apparatus 50 illustrated in FIG. 12, a rear mirror 51 that reflects some laser light while allowing some of the laser light to pass, and an output coupler 58 that reflects some laser light while allowing some of the laser light to pass. The rear mirror 51 and the output coupler 58 may form an optical resonator. Here, it is preferable for the reflectance of the rear mirror 51 to be higher than the reflectance of the output coupler 58.

### 5.1.2.2 Embodiment Including Ring Resonator

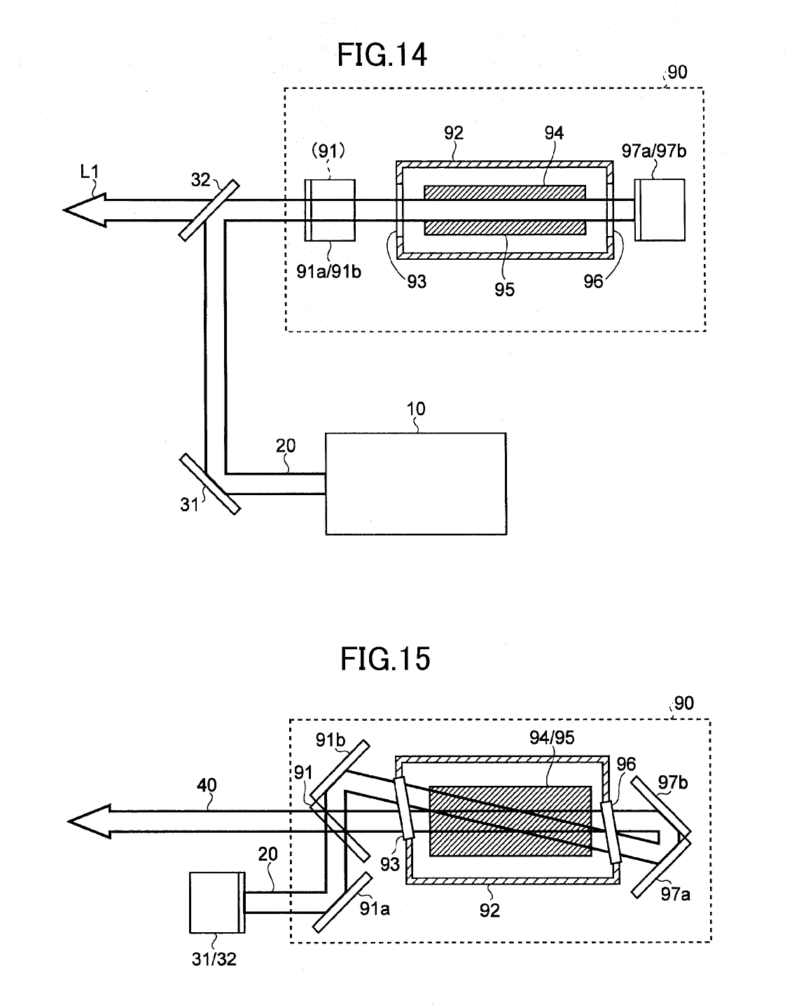

Next, a case where a power oscillator including a ring resonator is used as the amplifying apparatus 50 will be described as an example. FIGS. 14 and 15 schematically illustrate the overall configuration of an amplifying apparatus 90 that employs a power oscillator including a ring resonator. FIG. 14 is a side view of the amplifying apparatus 90, whereas FIG. 15 is a top view of the amplifying apparatus 90.

As shown in FIGS. 14 and 15, the amplifying apparatus 90 may include high-reflecting mirrors 91a, 91b, 97a, and 97b, an output coupler 91, and a chamber 92. The high-reflecting mirrors 91a, 91b, 97a, and 97b and the output coupler 91 may form a multipass optical path through which the pulsed laser light 20 passes through the amplification region within the chamber 92 multiple times. The output coupler 91 may be a partially-reflecting mirror. The chamber 92 may be disposed in the optical path formed by the high-reflecting mirrors 91a, 91b, 97a, and 97b and the output coupler 91. Note that the amplifying apparatus 90 may further include a slit (not shown) that adjusts the beam profile of the pulsed laser light 20 that travels within the amplifying apparatus 90. A gain medium such as an excimer gas may be injected into the chamber 92 so as to fill the amplification region. The gain medium may contain, for example, one of Kr gas and Ar gas, as well as F₂ gas and Ne, and may further contain an extremely small amount of Xe gas.

In the stated configuration, the pulsed laser light 20 outputted from, for example, the solid-state laser device 10 may enter into the amplifying apparatus 90 via a high-reflecting mirror 31 and a high-reflecting mirror 32. The pulsed laser light 20 that has entered may first enter into the chamber 92 via a window 93 after being reflected by the high-reflecting mirrors 91a and 91b. The pulsed laser light 20 that has entered into the chamber 92 may be amplified when passing through an amplification region between two discharge electrodes 94 and 95 where a voltage has been applied. The amplified pulsed laser light 20 may be emitted from the chamber 92 through the window 96. The emitted pulsed laser light 20 may then once again enter into the chamber 92 via the window 96 after being reflected by the high-reflecting mirrors 97a and 97b. After this, the pulsed laser light 20 may once again be amplified when passing through the amplification region within the chamber 92. The amplified pulsed laser light 20 may be emitted from the chamber 92 through the window 93 as the pulsed laser light 40.

The pulsed laser light 20 that has passed through the amplification region within the chamber 92 twice in this manner may then be partially outputted via the output coupler 91. Meanwhile, the remaining laser light that has been reflected by the output coupler 91 may be amplified by once again traveling through an optical path formed by the high-reflecting mirrors 91b, 97a, and 97b and the output coupler 91.

The aforementioned descriptions are intended to be taken only as examples, and are not to be seen as limiting in any way. Accordingly, it will be clear to those skilled in the art that variations on the embodiments of the present disclosure can be made without departing from the scope of the appended claims.

The terms used in the present specification and in the entirety of the scope of the appended claims are to be interpreted as not being limiting. For example, wording such as “includes” or “is included” should be interpreted as not being limited to the item that is described as being included. Furthermore, “has” should be interpreted as not being limited to the item that is described as being had. Furthermore, the indefinite article “a” or “an” as used in the present specification and the scope of the appended claims should be interpreted as meaning “at least one” or “one or more”.

What is claimed is:

1. A solid-state laser amplifier that is used with at least one master oscillator configured to output seed laser light and that is configured to amplify the seed laser light, the solid-state laser amplifier comprising:
a first amplifying module including a first optical system having two focusing optical systems disposed so that the focal points of the two focusing optical systems essentially match at a first position, and a first solid-state laser element, located near said first position, disposed so that a surface into which laser light enters is tilted at essentially a Brewster's angle relative to an optical path of the laser light; and
a second amplifying module including a second optical system having two focusing optical systems disposed so that the focal points of the two focusing optical systems essentially match at a second position, and a second solid-state laser element, located near said second position, disposed so that a surface into which laser light that has passed through said first amplifying module enters is tilted at essentially a Brewster's angle relative to an optical path of the laser light, and disposed so that a second plane of incidence of said second solid-state laser device into which said laser light enters is rotated, in a rotation direction central to said optical path, relative to a first plane of incidence of said first solid-state laser element into which said laser light enters.

2. The solid-state laser amplifier according to claim 1,
wherein the angle of said rotation is greater than 45 degrees and less than 135 degrees.

3. The solid-state laser amplifier according to claim 1,
wherein the angle of said rotation is essentially 90 degrees.

4. The solid-state laser amplifier according to claim 1, further comprising:
a first optical retarder configured to rotate a polarization direction of the laser light outputted from said first amplifying module at essentially the same rotation angle, in said rotation direction, as the rotation angle of said second plane of incidence relative to said first plane of incidence.

5. The solid-state laser amplifier according to claim 4,
wherein said seed laser light is configured to enter into said first solid-state laser element as P-polarized linearly-polarized light.

6. The solid-state laser amplifier according to claim 4, further comprising:
a folding mirror disposed in the optical path of the amplified laser light outputted from said second amplifying module; and
a light entry/exit module, located upstream from said first amplifying module in the optical path of said laser light, configured to transmit said seed laser light entering toward the first amplifying module and to reflect the amplified laser light that has been reflected by said folding mirror, entered into the first amplifying module, and exited from the first amplifying module.

7. The solid-state laser amplifier according to claim 6,
wherein said light entry/exit module includes a polarizing element, a polarization direction control element capable of controlling the polarization direction of entering laser light, and a third optical retarder.

8. The solid-state laser amplifier according to claim 4, further comprising:
a second optical retarder, located in the optical path of the amplified laser light outputted from said second amplifying module, that rotates the polarization direction of the amplified laser light; and
an output mirror located in the optical path of amplified laser light that passes through said first amplifying module and said second amplifying module two or more times and is outputted from the second amplifying module,
wherein said second optical retarder returns the polarization direction of said laser light that has been rotated by said first optical retarder to essentially the polarization direction prior to the rotation performed by the first optical retarder; and
the laser light that has passed through said second optical retarder once again enters into said first amplifying module.

9. The solid-state laser amplifier according to claim 1, further comprising:
a light relay module, located upstream from said first amplifying module in the optical path of said laser light, that transmits said laser light entering toward the first amplifying module and reflects the amplified laser light emitted from the first amplifying module; and
a folding mirror that folds the optical path of the laser light that has passed through said first amplifying module once,
wherein said amplified laser light reflected by said light relay module enters into said second amplifying module.

10. The solid-state laser amplifier according to claim 9,
wherein said light relay module includes a polarizing element, a polarization direction control element capable of controlling the polarization direction of entering laser light, and a second optical retarder.

11. A laser light amplifier comprising:
at least one master oscillator configured to output seed light;
at least one pumping laser configured to output pumping laser light;
the solid-state laser amplifier according to claim 1;
a first dichroic mirror, disposed between said first solid-state laser element and said at least one pumping laser, configured to reflect said seed light and transmit said pumping laser light; and
a second dichroic mirror, disposed between said second solid-state laser element and said at least one pumping laser, configured to reflect said seed light and transmit said pumping laser light.

12. A solid-state laser device comprising:
the solid-state laser amplifier according to claim 1;
a master oscillator configured to output said laser light to be inputted into said amplifier; and
a wavelength converter configured to convert the wavelength of the amplified laser light outputted from said amplifier.

13. A laser device comprising:
the solid-state laser device according to claim 12; and
an amplification device that amplifies laser light outputted from said solid-state laser apparatus.
